(19) United States
(12) Patent Application Publication
(10) Pub. No.: US 2009/0269914 A1
(43) Pub. Date: Oct. 29, 2009

(54) PROCESS FOR FORMING A DIELECTRIC ON A COPPER-CONTAINING METALLIZATION AND CAPACITOR ARRANGEMENT

(75) Inventors: Alexander Gschwandtner, Munchen (DE); Juergen Holz, Dresden (DE); Michael Schrenk, Diessen am Ammersee (DE)

Correspondence Address: BRINKS HOFER GILSON & LIONE/INFINEON;INFINEON, PO BOX 10395, CHICAGO, IL, 60610, US

(73) Assignee: Infineon Technologies AG, Munich (DE)

(21) Appl. No.: 12/497,949

(22) Filed: Jul. 6, 2009

Related U.S. Application Data
(62) Division of application No. 11/414,414, filed on Apr. 28, 2006.
Application No. 11/414,414 is a continuation of application No. PCT/EP2004/052594, filed on Oct. 20, 2004.

(30) Foreign Application Priority Data
Oct. 30, 2003 (DE) DE 10350752.3

(51) Int. Cl. H01L 21/46

(52) U.S. Cl. 438/584; 257/E21.482

(57) ABSTRACT

Process for forming a dielectric. The process may include forming the dielectric on a metallization and capacitor arrangement. The process allows the direct application of a dielectric layer to a copper-containing metallization. Accordingly, two process gases may be excited with different plasma powers per unit substrate area, or one process gas may be excited with a plasma and another process gas may not be excited.

### PRIORITY CLAIM

This application is a divisional application of U.S. Ser. No. 11/414,414 filed Apr. 28, 2006, which is a continuation of international application PCT/EP2004/052594 filed Oct. 20, 2004, which claims priority to German Patent Application No. DE 10350752.3 Filed Oct. 30, 2003, all of which are incorporated in their entirety by reference herein.

### BACKGROUND

1. Field of the Invention

The present invention is related to a process for forming a dielectric.

2. Description of Related Art

The main electrical properties of a dielectric include the leakage current or tracking current, the breakdown voltage, and the reliability. Capacitor arrangements have been disclosed in which a metallically conducting barrier layer has been applied to a copper metallization before the dielectric is produced. The application and patterning of the metallically conducting barrier layer entails additional process steps. Moreover, the conductivity of the barrier layer is lower than that of the metallization, with the result that the electrical properties of the capacitor are reduced. Moreover, conducting barrier layers do not always completely fulfill their barrier function.

In view of the above, it is apparent that there exists a need for an improved process for forming a dielectric.

### SUMMARY

A process for forming a dielectric on a copper-containing metallization is provided. The process includes the steps of producing a metallization on a substrate, supplying at least two process gasses and forming a dielectric having at least two types of constituents which originate from different process gasses. In addition, the metallization contains copper as a metallization constituent. Further, the process may include forming the dielectric adjacent to the metallization, exciting the two process gases with different plasma powers per unit substrate area, or exciting one process gas with a plasma, while the other process gas is not excited.

These processes prevent the premature decomposition of process gas which is not excited or is only weakly excited. This decomposition would prevent or greatly disrupt the formation of a high-quality dielectric on copper. On the other hand, strong excitation of the other process gas is also a precondition for the formation of a high-quality dielectric on copper.

In one embodiment, the process also includes using at least one problematic or critical process gas that either itself or from one of its constituents would form an auxiliary phase. The auxiliary phase having a considerable adverse effect on the electrical properties of a dielectric, when at least one metallization constituent is excited without additional measures or if a limit of plasma power per unit exposed substrate area is exceeded. The limit of plasma power would not be exceeded for the problematic process gas, for example, below 0.1 W/cm² or 0.5 W/cm² of substrate area, referenced on the basis of the externally applied power.

In another embodiment, the process includes the steps of:

forming the dielectric adjacent to the metallization, the dielectric containing at least one type of problematic constituents which originate from a problematic process gas, and the dielectric containing at least one type of unproblematic constituents which originate from at least one unproblematic process gas in the process gas mixture, and

setting the ratio of the problematic process gas to the unproblematic process gas such that the ratio of the number of problematic compound constituents in the process gas mixture and the number of unproblematic compound constituents in the process gas mixture is less than 10 percent or less than 0.1 percent of the ratio of the number of problematic compound constituents in the dielectric and the unproblematic compound constituents in the dielectric. One compound constituent is, for example, silicon. The other compound constituent is, for example, nitrogen.

In this embodiment of the process, the proportion of problematic constituents in the process gas mixture is particularly substoichiometric in relation to the proportion of problematic constituents in the dielectric, so that even based on the substoichiometry the formation of the disruptive auxiliary phase is reduced.

The lower limit for the proportion of the problematic constituents is set by the required growth rates. For example, the percentages mentioned may be greater than 0.01 percent or greater than 0.001 percent.

If the dielectric contains a plurality of problematic constituents, the abovementioned condition should be satisfied for each problematic constituent in order to prevent the formation of the auxiliary phase.

In another embodiment, the dielectric is produced with the aid of a deposition process in which the process gases are supplied separately from one another, beginning with the supply of unproblematic process gas. This refinement is based on the consideration that the unproblematic process gas forms a thin protective layer on the metallization, impeding or preventing the formation of disruptive auxiliary phases. In the process, only one atomic layer or only a few atomic layers is/are formed in each cycle, for which reason the process is also referred to as atomic layer deposition (ALD). In further cycles, the protective action is constantly reinforced compared to the first cycle, so that in one configuration other deposition processes may also be used in turn.

The separate supply of the process gases also ensures that there are no reaction products leading to uncontrolled flocculation and to inhomogenous atomic layers.

The metallization may also be cleaned immediately before the production of the dielectric, for example by back-sputtering or by a wet-chemical cleaning step.

The dielectric may be applied without an additional barrier layer arranged between the dielectric and the lower electrode. This allows new integration concepts which are considerably simpler than previous concepts and are explained in more detail below on the basis of the exemplary embodiments, in particular what is known as a POWER-LIN concept, in which linear capacitors are arranged, without an additional photolithographic step, between operating voltage lines made from copper in copper metallization layers. A PAD-LIN-CAP concept may also be used, in which capacitors are formed without an additional photolithographic step between the last copper metallization layer and an aluminum layer located above, the aluminum layer being used for bonding purposes.

The process may also be used to produce dielectrics for applications other than capacitors.

In yet another embodiment, the dielectric, i.e. an electrically nonconductive material, is formed from a material which is a diffusion barrier for copper and which counteracts the electromigration of copper. Additional layers for achieving these effects are not deposited, and in particular no electrically conductive barrier layers are deposited. Silicon nitride is one suitable material, since it is simple to produce and is very compatible with the other standard materials used for semiconductor circuits. A silicon-containing process gas, which is problematic on account of the silicon fraction, is used to produce silicon nitride. Therefore, without an additional measure, a silicide could form in considerable quantities as a disruptive auxiliary phase, in particular copper silicide. Suitable silicon-containing process gases include silane, disilane, dichlorosilane, trichlorosilane, bis(tertbutylamino)silane or BTBAS or a gas mixture comprising at least two of these gases.

In another embodiment, the metallization fraction of the copper is at least ninety percent by volume of the metallization. Direct deposition of a dielectric on copper can for the first time be achieved in a simple way by the processes described.

A dielectric may also be formed on a metallization where the process gases from which the constituents of the dielectric originate have been selected such that neither the process gases nor their constituents form an auxiliary phase with the copper of a metallization, which would have a considerable adverse effect on the electrical properties of the dielectric. The formation of disruptive auxiliary phases can also be prevented by suitable selection of the material of the dielectric and of the process gases. As such, the dielectric may be applied without an additional barrier layer arranged between the dielectric and the lower electrode. This likewise allows the new integration concepts referred to above to be implemented. However, high-quality dielectrics for applications other than in capacitors are also produced by the process according to the invention.

In addition, the dielectric may be produced from aluminum nitride. As such, the process gases used may include trimethylaluminum and a nitrogen-containing gas. Therefore, neither the dielectric nor the process gas contains problematic constituents such as oxygen or silicon which lead to the formation of disruptive auxiliary phases. In particular, copper silicide or any copper oxide with these gases will not be formed.

In another embodiment, the dielectric is produced with the aid of a deposition process in which the process gases comprising constituents for forming the dielectric are supplied separately from one another. The gases may be provided cyclically, for example in at least five cycles or at least ten cycles. This process is referred to as atomic layer deposition and leads to dielectric layers with a particularly uniform layer thickness, compared to other deposition processes. By way of example, aluminum nitride can be deposited in a sufficiently uniform layer thickness by atomic layer deposition. The thickness of the dielectric or dielectric stack may be in the range from three nanometers to fifty nanometers.

In yet another embodiment, a process gas containing a constituent which is also present in the dielectric is excited less strongly than at least one other process gas, for example less strongly than a process gas containing a constituent which is also present in the dielectric. Accordingly, the problematic process gas may be excited less strongly. The result of this is that the formation of the auxiliary phases is effectively prevented not only by the reduced concentration of the problematic constituents but also by the reduced excitation state of the problematic gas. The additional excitation of the unproblematic gas, on the other hand, leads to the problematic constituents predominantly reacting with the excited constituents to form the dielectric.

In an atomic layer deposition process, the activation of one process gas leads to increased interaction with the surface of the metallization, in particular to uniform accumulation of constituents which then form the dielectric when the other process gas is admitted.

Moreover, excessively strong excitation of certain process gases, for example of silicon-containing gases, in both CVD (chemical vapor deposition) and atomic layer deposition may lead to premature decomposition and, as a corollary effect, also to undesirable deposition, for example of amorphous or polycrystalline silicon in the excitation chamber, for example in an antechamber.

Further, the more strongly excited process gas may be excited separately from the less strongly excited or unexcited process gas, preferably in a chamber which is separate from a reaction chamber. Processes with a separate excitation chamber are also known as remote plasma processes. However, in the case of atomic layer deposition the reaction chamber is also used for excitation, since the process gases are located in the reaction chamber at different times. In particular a plasma which is generated, for example, by being coupled in inductively, by being coupled in capacitively or in some other way is suitable for excitation.

In another embodiment, the dielectric is the dielectric of a capacitor, in particular of a capacitor with two metallic electrodes between which the dielectric is arranged. In a further refinement, the entire dielectric of the capacitor is produced by the process according to the invention or one of its refinements and therefore with a small number of different process steps.

In an alternative embodiment, the dielectric is produced as a layer stack. Therefore, according to a process of the invention, at least one further dielectric layer is produced adjacent to the dielectric layer, the further layer having a different material composition and/or being produced by a different process and/or using different process parameters than the dielectric layer. After the formation of auxiliary phases has initially been prevented, the dielectric which has already been applied then acts as a protective layer. Materials with a higher relative dielectric constant than the dielectric applied first can be applied without problems, for example aluminum oxide, in particular aluminum trioxide Al₂O₃, aluminum oxynitride, tantalum oxide, in particular tantalum pentoxide Ta₂O₅, tantalum oxynitride, hafnium oxide, barium strontium titanate or the like. Aluminum oxides can be formed particularly easily starting from an aluminum nitride layer. In particular, however, the materials aluminum nitride and silicon nitride are also used, both with a base layer of aluminum nitride and with a base layer of silicon nitride.

In the first deposition step, by way of example, a deposition condition is selected which in particular does not produce any auxiliary phases and results in a good barrier layer, for example with a thickness of 5 to 10 nm. Then, in a second deposition step, the deposition is optimized to the best dielectric properties, for example to a stoichiometric ratio of the compound constituents in the dielectric.

In another embodiment, it has surprisingly been established that the electrical properties of the dielectric of the capacitor are improved further if an upper layer of the dielectric stack is also formed using a process according to the invention or one of its refinements.

The invention also relates to an integrated capacitor arrangement, in particular a capacitor arrangement produced by the process according to the invention. Therefore, the abovementioned technical effects also apply to the capacitor arrangement.

Further objects, features and advantages of this invention will become readily apparent to persons skilled in the art after a review of the following description, with reference to the drawings and claims that are appended to and form a part of this specification.

### BRIEF DESCRIPTION OF THE DRAWINGS

The text which follows explains exemplary embodiments of the invention on the basis of the accompanying drawings, in which:

FIG. 1 shows an installation for carrying out an RPE-CVD Si₃N₄ process,

FIG. 2 shows process steps for carrying out an RPE-ALCVD Si₃N₄ process or an RPE-ALCVD AIN process,

FIG. 3 shows a capacitor arrangement which has been produced using two additional mask steps,

FIG. 4 shows a capacitor arrangement which has been produced with one additional mask step, and

FIG. 5 shows a capacitor arrangement which does not require any additional mask steps.

### DETAILED DESCRIPTION

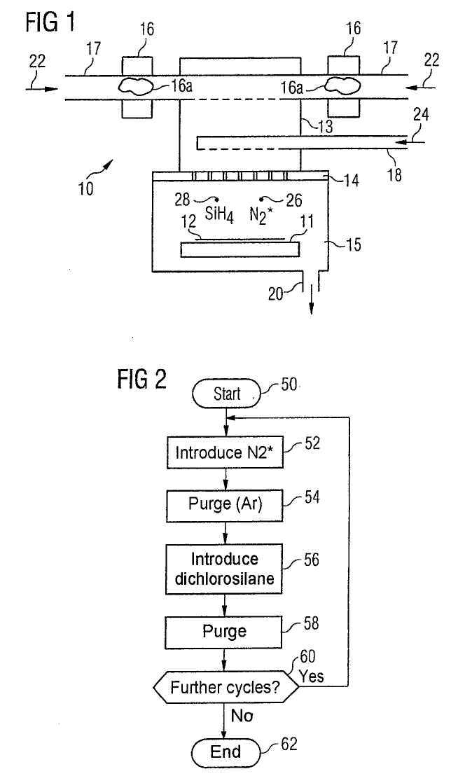

FIG. 1 shows a process reactor 10 that may be used in an RPE-CVD (remote plasma enhanced chemical vapor deposition) Si₃N₄ process. However, the process reactor 10 can also be used to carry out the atomic layer processes explained below with reference to FIG. 2.

The process reactor 10 includes a process chamber 15, in which a substrate 12 that is to be coated, for example a semiconductor wafer, is arranged on a substrated electrode 11. An inlet electrode 14, which has a multiplicity of small passage openings for the process gases, is arranged at the ceiling of the process chamber 15 above the top side, which is to be coated, of the substrate 12 to be coated.

A high-frequency voltage is applied between the electrodes 11 and 14 when a plasma is to be generated in the process chamber, for example during the processes explained below with reference to FIG. 2.

If separate decomposition and excitation of process gases is required, the process gases may be supplied separately via feed lines 17. Each feed line 17 is assigned an energy source 16, for example a microwave emitter, with the aid of which a plasma 16a can be ignited in the associated feed line. The feed lines 17 open out in an antechamber 13, which is connected to the process chamber 15 via the passage openings in the inlet electrode 14.

If only one process gas is to be excited, one feed line 17 and one energy source are sufficient. The feed lines may be produced, for example, from ceramic material.

As well as process gases, in other exemplary embodiments inert gases are also excited in the feed lines 17, for example argon or helium. A feed 18, which likewise opens out into the antechamber 13, is used to supply process gases which are not intended for excitation. Reaction products and unconsumed process gases are sucked out of the process chamber 15 with the aid of a pump 20.

By way of example, the following operating parameters may be used:

microwave power from an energy source 16 of between 700 and 850 Watts,

pressure in the process chamber 15 of between 5 Pa and 100 Pa,

high-frequency power between 0.02 and 0.1 W/cm²,

nitrogen-containing gas flow rate from 200 to 400 sccm/min,

silane flow rate 10 to 30 sccm/min.

For deposition of silicon nitride by the process according to the invention, by way of example nitrogen is admitted through the feed lines 17 and excited with the aid of the remote plasma 16a, as denoted by arrows 22. Silane SiH₄ is introduced without excitation through feed line 18, as denoted by arrow 24. Excited nitrogen radicals 26 and silane molecules 28 react on the hot surface of the substrate 12 to form silicon nitride at temperatures between 200° C. and 500° C. In one embodiment, no plasma is ignited in the process chamber 15. In another embodiment, a low-power plasma is ignited in the process chamber 15 by the abovementioned high-frequency power, so that the silane is also weakly excited.

The ratio between silane and nitrogen is set in such a way, as to avoid the formation of copper silicide.

FIG. 2 shows process steps involved in carrying out an RPE-ALCVD (remote plasma enhanced atomic layer chemical vapor deposition) Si₃N₄ process or an RPE-ALCVD AIN process. By way of example, the process reactor 10 is used to carry out the processes.

The RPE-ALCVD Si₃N₄ process will be explained first of all. The process begins in process step 50 with a preliminary cleaning step, for example a back-sputtering step. Then, in a process step 52 which follows the process step 50, excited nitrogen gas is introduced into the process chamber via the feed lines 17, without any further process gas being present in the process chamber 15, in particular without any silicon-containing process gas being present.

Then, in a subsequent process step 54, the process chamber 15 is purged with an inert gas, for example with argon. The argon is introduced into the process chamber for example through a feed line (not shown). Residues of the nitrogen-containing gas are completely sucked out of the process chamber 15 with the aid of a pump 20.

In a following process step 56, after purging, a silane-containing process gas, for example dichlorosilane, is introduced via the feed line 18, once again without any further process gas being present in the process chamber 15. The dichlorosilane reacts with nitrogen which has accumulated at the surface of the substrate 12 in process step 52 to form a monolayer of silicon nitride. The silane-containing process gas is not excited. In another exemplary embodiment, the silane-containing process gas is weakly excited.

The process step 56 is followed by purging again in a process step 58. The procedure in this step may be the same as that explained above for process step 54.

Once the dichlorosilane has been completely sucked out of the reaction chamber 15, a process step 60 checks whether the predetermined number of cycles has been reached. In the exemplary embodiment, 30 cycles are to be completed, resulting in a layer thickness of, for example, three nanometers. If further cycles are to be carried out, process step 60 is immediately followed by process step 52. The process may include a loop comprising process steps 52 to 60, during which nitrogen and dichlorosilane are alternately introduced into the process chamber 15 so that a plurality of individual layers of silicon nitride are formed on the substrate 12.

The loop made up of process steps 52 to 60 may be departed from in process step 60 when the predetermined number of cycles has been reached. Once the predetermined number of cycles has been reached, process step 60 is immediately followed by a process step 62 in which the process for producing the dielectric is ended. Optionally, further layers of a dielectric stack are produced from different layers using other processes or different process parameters.

The process which has been explained with reference to FIG. 2 allows the deposition of a multilayer silicon nitride layer of a good quality at temperatures in the range from 200 to 500 degrees Celsius.

The text which follows explains the RPE-ALCVD AIN process, which is carried out in the same way as the RPE-ALCVD Si₃N₄ process apart from the following differences:

in process step 56, an aluminum-containing process gas, for example trimethyl aluminum, is supplied via the feed line 18 instead of the silane-containing process gas.

It is possible to produce a multilayer aluminum nitride layer of a good quality, i.e. with a low defect density and a high barrier action.

Then, in other exemplary embodiments, at least one further dielectric layer of a dielectric stack is produced, but using a conventional process. Very good results may be achieved with a layer stack which contains, in the following order, an RPE-CVD Si₃N₄ layer, an ALD (atomic layer deposition) layer of Al₂O₃ and an RPE-CVD Si₃N₄ layer.

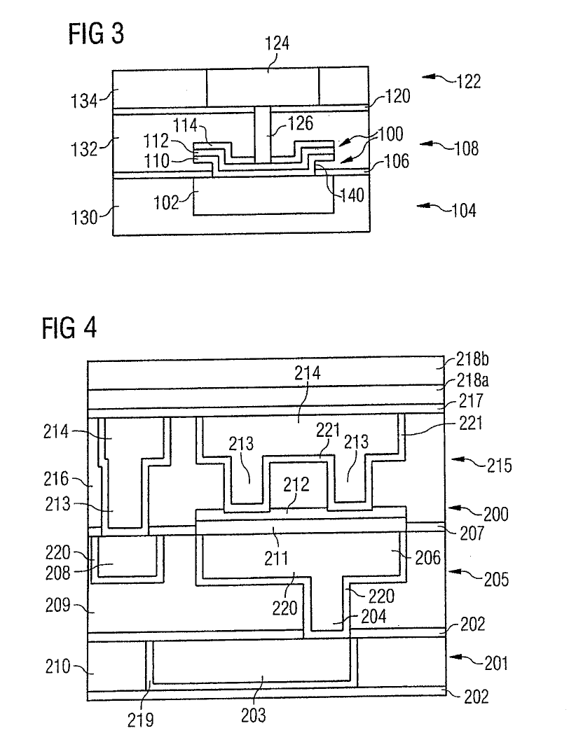

FIG. 3 shows a capacitor arrangement 100 which has been produced using two additional mask steps. The capacitor arrangement 100 includes a bottom electrode 102 of copper or a copper alloy with an alloying fraction of substances other than copper of less than five percent. The bottom electrode 102 is contained in a planar metallization layer 104. The metallization layer 104 is terminated by a diffusion barrier layer 106 which has been deposited using a conventional process. Although this is not illustrated in FIG. 3, the bottom electrode 102 is surrounded by a barrier layer on all sides.

Moreover, the capacitor arrangement includes a metallization layer 108 further away from the substrate. The metallization layer 108 may have, at increasing distance from the substrate:

an electrically insulating dielectric layer 110 of silicon nitride Si₃N₄ or of aluminum nitride AIN or comprising a layer stack,

an electrically conductive capping electrode 112, for example of titanium nitride TiN, tantalum nitride TaN or the like, and

a silicon nitride layer Si₃N₄.

The metallization layer 108 is terminated by an electrically insulating barrier layer 120. A metallization layer 122 arranged above the metallization layer 108 includes an interconnect 124, for example a copper interconnect. A via 126 leads from the interconnect 124 to the capping electrode 112. The metallization layers 104, 108 and 122 each include an intralayer dielectric 130, 132 and 134, respectively, for the electrical insulation of interconnects within a metallization layer 104, 108 and 122. By way of example, silicon dioxide or a low-k dielectric is used as material for the intralayer dielectric 130, 132 and 134.

A first sublayer of the intralayer dielectric 132 is applied, for example in a layer thickness which is less than one third of the final thickness of the intralayer dielectric 132. In a first additional photolithographic step, the position of a recess 140 in which the capacitor 100 is to be produced is defined. The recess 140, after the exposure and developing of a resist, is etched, for example using an RIE (reactive ion etching) process. The recess 140, after the etching, penetrates through the first sublayer of the intralayer dielectric 132 and the barrier layer 106, so that the base of the recess 140 rests on the bottom electrode 102. The bottom electrode 102 projects beyond the base of the recess 140 on all sides.

Then, the dielectric layer 110 is deposited over the entire surface using one of the processes explained with reference to FIGS. 1 and 2. If appropriate, further sublayers of the dielectric layer 110 are then produced from other materials or using other processes.

Then, the capping electrode layer 112 is deposited over the entire surface. This is optionally followed by deposition of the silicon nitride layer 114 over the entire surface. The deposition of layers 110 to 114 is conformal.

Then, a second additional photolithographic step is carried out for defining the position of the edge of the capping electrode 112. After exposure and developing of a resist, etching is carried out, stopping at the lower sublayer of the intralayer dielectric 132. In the exemplary embodiment, the edge of the capping electrode 112 is completely outside the recess 140 and has a contour corresponding to the contour of the bottom electrode 102.

Then, the sublayer of the intralayer dielectric 132 is deposited. After an optional planarization step, processing then continues with the production of the via 126.

FIG. 4 shows a capacitor arrangement 200 which has been produced using just one additional mask step, in cross section. A substrate having a multiplicity of semiconductor components, e.g. transistors, is located beneath the arrangement illustrated. A lower, planar metallization layer 201 may include interconnects for lateral current transport, e.g. an interconnect 203, between nonconducting diffusion barriers 202. The interconnect 203 is connected to a lower electrode 206, arranged in a second metallization layer 205, of the capacitor arrangement 200 by means of a via 204 for vertical current transport. In an exemplary embodiment, an interconnect 208 may be located in the metallization plane 205 to the left-hand side of the electrode 206. The lower electrode 206 and the interconnect 208 are embedded in an interdielectric 209 in order for them to be insulated from one another, for example in silicon dioxide. By contrast, an interdielectric 210 insulates the interconnects 203 of the lower metallization layer 203 from one another.

A capacitor dielectric 211, for example a single-layer or multilayer dielectric, is arranged on the lower electrode 206. An upper electrode 212 is arranged on the interdielectric 211. In the region of the upper electrode 212, the capacitor dielectric has a thickness which is greater than the thickness of a barrier layer 207 arranged at the same level as the capacitor dielectric 211.

The upper electrode 212 and the interconnect 208 are electrically conductively connected by means of vias 213 to interconnects 214 in a third metallization layer 215, which includes an interdielectric 216. A nonconducting diffusion barrier 217 and further passivation layers 218a and 218b are located above the metallization layer 215.

The interconnects 203, 208 and 214, the lower electrode 206, and the vias 204, 213 may be made from a copper alloy or from pure copper, for example with the aid of a dual damascene process. For example, conducting barrier layers 219, 220 and 221 may comprise titanium nitride and may be introduced into the trenches or holes. Further, the trenches or holes may be filled with copper.

The diffusion barriers 202, 207, 217, the capacitor dielectric 211, and the passivation layer 218b may comprise silicon nitride Si₃N₄. In addition, the passivation layer 218a may comprise silicon dioxide.

Deviations from the known dual damascene process may ensue when producing the capacitor 200. After the planarization of the metallization layer 205, for example by a chemical mechanical polishing process, silicon nitride may be deposited over the entire surface of the capacitor dielectric 211 and of the diffusion barrier 207. This involves using a process which has been explained above with reference to FIGS. 1 and 2. In an alternative exemplary embodiment, aluminum nitride may be used instead of the silicon nitride as material for the barrier layer 207 and the capacitor dielectric 211 and is applied using the process which has been explained above with reference to FIG. 2.

Following the deposition of the material for the barrier layer 207 or for the capacitor dielectric 211, a metallic layer, for example a titanium nitride layer, may be deposited over the entire surface to form the electrode 212. Alternatively, the electrode 212 may be formed as a layer stack. Then, an additional photolithographic step is carried out to define the edge of the electrode 212. The developing and exposure of a resist is followed by etching, stopping at the barrier layer 207 with a slight overetch. The further processing may then be completed.

In another exemplary embodiment, a silicon nitride layer may also be applied to the electrode, serving as an etching stop, inter alia, during the etching of the vias 213. In another exemplary embodiment, just one via is used instead of a plurality of vias for connecting an electrode 206 or 212. The lower electrode 206 can also be connected by a plurality of vias or from “above”, i.e. from a side remote from the semiconductor substrate.

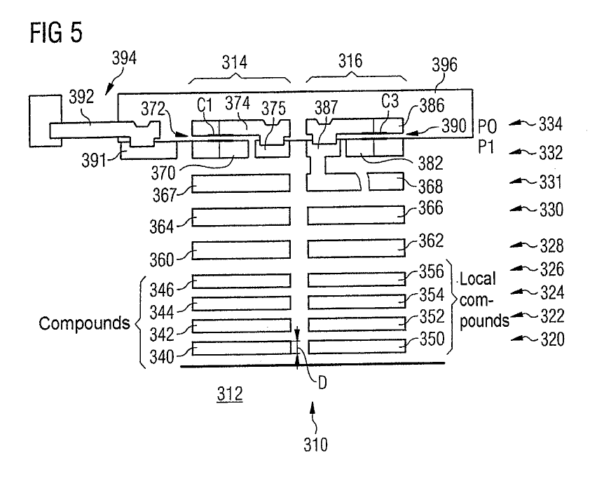

FIG. 5 shows capacitor arrangements which do not require any additional mask step. An integrated circuit arrangement 310 includes, in a silicon substrate 312, a multiplicity of integrated semiconductor components, although these are not illustrated in FIG. 5. The components arranged in the silicon substrate 312 form two spatially separate regions, namely an analog part 314 and a digital part 316. The analog part 314 processes primarily analog signals, i.e. signals which have a continuous range of values. By contrast, the digital part 316 processes predominantly digital signals, i.e. signals which, for example, have only two values assigned to two switching states.

Moreover, above the silicon substrate 312, the circuit arrangement 310 may include at least four metallization layers, and in one exemplary embodiment nine metal layers 320 to 334, between which no further metal layers, but rather insulating layers, are arranged. The metal layers 320 to 334 are each arranged in one plane. The planes of the metal layers 320 to 334 are arranged parallel to one another and also parallel to the main surface of the silicon substrate 312. The metal layers 320 to 334 each extend in both the analog part 314 and the digital part 316.

The bottom four metal layers 320, 322, 324 and 326 in the analog part 314 include, in the order listed, connecting sections 340, 342, 344 and 346, respectively, which form connections between the components of the analog part 314. FIG. 5 indicates a multiplicity of interconnects in the form of blocks. Of course, there are also interconnects between these blocks for the connection of analog part 314 and digital part 316. In the digital part 316, the metal layers 320, 322, 324 and 326 include, in this order, connecting sections 350, 352, 354 and 356, respectively, which form local connections between the components of the digital part 316. Perpendicular to the substrate 312, the connecting sections 340 to 356 have a thickness D of, for example, 100 nm.

In the analog part 314, the metal layer 328 includes connecting sections 360 which carry analog signals and connect the components of the analog part 314. In the digital part 316, the metal layer 328 includes connecting sections 362 which connect the components of the digital part 316 and, therefore, carry digital signals. The metal layer 330 likewise includes connecting sections 364 for analog signals in the analog part 314 and connecting sections 366 for digital signals in the digital part 316.

The metal layer 331 includes a connecting section 367 in the analog part 314, which covers the entire surface of the analog part 314 and is used to shield the analog part 314 from components located above it. By contrast, in the digital part 316 the metal layer 331 includes connecting sections 368 which, for example, carry an operating voltage or ground potential. The connecting sections 360 to 368 have a thickness double the thickness D.

The metal layers 332 and 334 form the top two metal layers. In the analog part 314, the metal layer 332 includes a bottom electrode 370 of a capacitor 372 with linear transmission function and a capacitance C1. The capacitor C1 is used to process analog signals, for example in an analog/digital converter. A capping electrode 374 of the capacitor 372 lies in the metal layer 334 above the electrode 370. The capping electrode 374 is connected to a connecting section 375 in the metal layer 332.

In the digital part 316, the metal layer 332 includes a connecting section 382 which carries an operating potential P1 of, for example, 2.5 volts. Above the connecting section 382 there is a connecting section 386 which carries a ground potential P0 of 0 volts. A capacitance C3 which belongs to a block capacitor is formed between the connecting sections 382 and 386. The connecting section 386 is connected by a connecting section 387 in the metal layer 332 and vias to a connecting section 368 in the metal layer 331.

At least the metal layer 332 contains copper-containing electrically conductive material, so that in particular the bottom electrode 370 of the capacitor 372 and the connecting section 382 contain copper. Further metal layers 320 to 334 optionally also contain copper.

The level of the capacitances C1 and C3 may be determined by the size of the overlapping electrodes 370 and 374 and/or of the overlapping connecting sections 370 to 386. Alternatively, the area-referenced capacitance between the connecting sections 370 and 374 and between 382 and 386 may be determined by the formation of an interlayer 390 which is located between the metal layers 332 and 334. The interlayer 390 is formed in such a way as to produce an area-referenced capacitance of, for example, greater than 0.5 fF/μm².

The connecting sections 370 to 386 have a thickness four times the thickness D and are therefore suitable in particular for carrying high currents, as occur in connecting sections 382 and 386 for supplying the operating voltage.

The capacitance C3 is formed from electrically conducting sections of two metallization layers 332 and 334 which, for example, do not carry any signals, but rather are used exclusively to carry the operating voltage. If signals are carried, the signal lines are designed with the same profile in both metallization layers.

In the situation shown in FIG. 5, this is, in the case of what is known as the “PAD-LIN-CAP” concept, the upper copper metallization layer and, on the latter, an aluminum metallization layer which contains at least 90 percent by volume aluminum. The aluminum metallization layer may also be used for bonding, as shown by bonding pad 392 in the metal layer 334 and a bonding opening 394 in a passivation 396. Bonding pad 392 is connected to a connecting section 391 in the metal layer 334.

The dielectric 390 between the two metallization layers 332 and 332 may be a dielectric or a dielectric stack which has been produced in accordance with one of the processes explained above. Linear capacitors C1, the capacitance of which is determined by the size of the copper plate 370, result in the mixed-signal part 314 of the chip. Capacitors C3 likewise result at line cross-overs in the digital part 316, but these capacitors are not parasitic and also not disruptive since they contribute to stabilizing the supply voltage. Since fewer metallization layers are generally required in the mixed-signal part 314 of the circuit 310 of the chip than in the digital part 316, this concept makes do without additional mask steps.

It is also possible for the above-described dielectric 390 or the above-described dielectric stack to be used for what is known as the “POWER-LIN-CAP” concept. In this case, the dielectric 390 or the dielectric stack is located between the last two copper metallization layers. The aluminum metallization layer is then no longer required and the bonding then takes place directly onto copper.

To summarize, in particular high-frequency circuits in BIPOLAR, BICMOS (BIpolar Complementary Metal Oxide Semiconductor) and CMOS technology (Complementary Metal Oxide Semiconductor) require capacitors with a high capacitance per unit area, for example higher than 0.7 fF/μm², and with low parasitic capacitances. The conventional MOS or MIS capacitors which have been used hitherto have the disadvantageous properties of being highly voltage dependent due to voltage-induced space charge regions and also having high parasitic capacitances due to the short distance from the substrate. These problems can be avoided by the use of MIM (metal insulator metal) capacitors, which are to be integrated in the metallization, in particular in a multilayer metallization, without altering and influencing the adjacent metal tracks. The intention is also for the minimum possible number of additional process steps, in particular additional photolithographic steps, to be required for the introduction of the MIM capacitors.

To obtain a capacitor which is free of defects and has a long service life, appropriate dielectric interfaces should be selected. In particular in the case of copper metallizations, the application of conventional dielectrics, without additional measures, leads to defect densities which are no longer acceptable and/or to reduced reliability. The primary causes of these defect densities are impurities in the dielectric caused by copper diffusion or auxiliary phases, as well as, copper hillocks that lead to singularities in the field distribution and/or to field peaks. These impurities and copper hillocks are reduced or prevented by the processes explained herein for the application of the dielectric.

As a person skilled in the art will readily appreciate, the above description is meant as an illustration of implementation of the principles this invention. This description is not intended to limit the scope or application of this invention in that the invention is susceptible to modification, variation and change, without departing from the spirit of this invention, as defined in the following claims.

I/We claim:

1. A process for forming a dielectric on a metallization, comprising the steps of:
producing a metallization on a substrate, the metallization containing copper as a metallization constituent;
supplying at least two process gases;
forming the dielectric adjacent to the metallization, the dielectric containing at least two types of constituents which originate from different process gases wherein a first process gas of the at least two process gases is excited with a greater plasma power than a second process gas of the at least two process gases.

2. The process as claimed in claim 1, wherein the first process gas is excited with a plasma and the second process gas is not excited.

3. The process as claimed in claim 1, wherein the at least two process gases are supplied as a process gas mixture.

4. The process as claimed in claim 3, wherein a silicon-containing process gas is supplied as a problematic process gas and a nitrogen-containing gas is supplied as an unproblematic process gas.

5. The process as claimed in claim 3, wherein a ratio of a problematic process gas to an unproblematic process gas is set such that a ratio of problematic constituents and unproblematic constituents in the process gas mixture is less than 0.1 percent of a ratio of problematic constituents and unproblematic constituents in the dielectric.

6. The process as claimed in claim 1, wherein the dielectric is produced with the aid of a deposition process, in which the at least two process gases are supplied to the metallization separately from one another.

7. The process as claimed in claim 6, wherein the at least two process gases comprises bis (terbutylamino) silane.

8. The process as claimed in claim 1, wherein the at least two process gases are supplied cyclically to the metallization in at least ten cycles.

9. The method as claimed in claim 1, further comprising at least one of the following steps:
forming the dielectric from a material which is a diffusion barrier to copper,
forming the dielectric from a material which counteracts the electromigration of copper,
forming the dielectric from silicon nitride, in particular from Si₃N₄, or from a material which contains silicon nitride,
supplying a silicon-containing process gas wherein the process gas comprises silane, disilane, dichlorosilane, trichlorosilane, bis (tertbutylamino) silane or a gas mixture comprising at least two of these gases,
supplying a nitrogen-containing gas wherein the nitrogen-containing gas includes nitrogen, ammonia gas or a mixture of nitrogen and ammonia gases.

10. The process as claimed in claim 1, wherein the metallization fraction amounts to at least five percent by volume of the metallization.

11. The process as claimed in claim 10, wherein the metallization fraction amounts to at least forty percent by volume of the metallization.

12. The process as claimed in claim 11, wherein the metallization fraction amounts to at least ninety percent by volume of the metallization.

13. The process as claimed in claim 1, wherein the first process gas is excited separately from the second process gas.

14. The process as claimed in claim 13, wherein the second process gas is contained in a chamber that is separate from a reaction chamber.

15. The process as claimed in claim 1, wherein the dielectric forms a capacitor dielectric of a capacitor, the capacitor having two metallic electrodes, the capacitor dielectric being arranged between the two metallic electrodes.

16. The process as claimed in claim 15, wherein an entire amount of the capacitor dielectric arranged between the two metallic electrodes is the dielectric.

17. The process as claimed in claim 1, further comprising the steps of:
forming a dielectric layer,
forming at least one further dielectric layer adjacent to the dielectric layer, the further layer having a different material composition and/or being produced by a different process and/or using different process parameters than the dielectric layer.

18. The process as claimed in claim 17, further comprising forming the further layer by oxidation.

19. The process as claimed in claim 17, further comprising forming the further layer by anodic oxidation.

20. The process as claimed in claim 17, further comprising the step of:
forming a dielectric layer after the further layer has been formed, in particular adjacent to the further layer.

21. The process as claimed in claim 17, wherein the further layer has a relative dielectric constant of greater than seven.

22. The process as claimed in claim 17, wherein the further layer comprises an oxide.

23. The process as claimed in claim 17, wherein the further layer comprises aluminum oxide, tantalum oxide or hafnium oxide.
